(19) United States
(12) Patent Application Publication
(10) Pub. No.: US 2009/0253232 A1
(43) Pub. Date: Oct. 8, 2009

(54) Microwave Cure of Semiconductor Devices

(76) Inventors: Gary Philip Thomson, Rowlett, TX (US); Peter Joseph Sakakini, Frisco, TX (US)

Correspondence Address: TEXAS INSTRUMENTS INCORPORATED, P O BOX 655474, M/S 3999, DALLAS, TX, 75265, US

(21) Appl. No.: 12/099,669

(22) Filed: Apr. 8, 2008

(51) Int. Cl. H01L 21/56; H01L 21/50

(52) U.S. Cl. 438/118; 438/127; 257/E21.502; 257/E21.499

(57) ABSTRACT

A method for curing an adhesive is disclosed. A preferred embodiment comprises securing a cover onto a substrate to enclose a MEMs device using an adhesive. The adhesive is either partially or fully cured using microwave radiation. Another preferred embodiment utilizes the microwave radiation to cure an encapsulant placed to protect a semiconductor device.

### TECHNICAL FIELD

The present invention relates generally to a system and method for manufacturing semiconductor device packages, and more particularly to a system and method for curing semiconductor device package adhesives and encapsulants.

### BACKGROUND

Adhesives and encapsulants are used for many reasons throughout the manufacturing of semiconductor devices. For example, an adhesive may be used to seal a cover over a microelectromechanical device (MEMs device), to attach a die to a substrate or wafer, or to encapsulate and protect a wafer. Traditionally, these adhesives and encapsulants have been cured by placing the adhesive (and the rest of the structure) into an oven, and using convective heat transfer to heat and cure the adhesive.

However, this thermal curing process has many problems associated with it. One of the larger problems is that by using convective heat transfer, the entire structure, and not just the material that is desired to be cured, is heated. Because different materials have different coefficients of thermal expansion, stresses will form as the different materials expand at different rates due to the heating. These stresses may cause defects in the device, shifts in the alignment of the materials, and reduce overall yields to an unacceptable level.

Further, thermal curing is a time consuming process. Typically, at least three to four hours or more are required to cure an adhesive or encapsulant in an oven. Such a length of time is not only lengthy in and of itself, but may easily become a bottleneck to the overall manufacturing process.

Additionally, the thermal cure process requires that the overall structure (for example, the substrate, MEMs device, adhesive and cover) be physically moved to the oven. Such a movement could easily cause the individual pieces to become mis-aligned. This could either reduce yield or else require a time-consuming break in the process so that any misalignments may be discovered and fixed.

Accordingly, what is needed is a method to cure adhesives and encapsulants that does not rely upon the time-consuming thermal convection curing of the adhesives and encapsulants.

### SUMMARY OF THE INVENTION

These and other problems are generally solved or circumvented, and technical advantages are generally achieved, by preferred embodiments of the present invention which cure an adhesive or encapsulant using microwave radiation.

In accordance with a preferred embodiment of the present invention, a method for curing an adhesive comprises providing a substrate and a cover and applying an adhesive to either the substrate or the cover. Once the adhesive is in place, the substrate and cover are placed into position and in contact with each other. To cure the adhesive, the adhesive is volumetrically heated with microwave radiation.

In accordance with another preferred embodiment of the present invention, a method for attaching a wafer or die to a substrate comprises adhering the wafer to the substrate by applying a single layer of an attach material between the substrate and the wafer. The attach material is then cured using microwave radiation.

In accordance with yet another preferred embodiment of the present invention, a method for encapsulating semiconductor wafers comprises applying an encapsulant to the semiconductor device. The encapsulant is at least partially cured by irradiating the encapsulant with microwave radiation.

An advantage of a preferred embodiment of the present invention is the reduced number of defects by only selectively heating the adhesive or encapsulant, thereby reducing the stresses normally caused by differing coefficients of thermal expansion.

A further advantage of a preferred embodiment of the present invention is that microwave curing is much quicker than thermal curing of the adhesive or encapsulant. This allows for much better overall process control and debottlenecking opportunities.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a perspective view of a MEMs device enclosed within a substrate by a cover in accordance with an embodiment of the present invention;

FIG. 2 illustrates a cut-away view of the structure of FIG. 1, illustrating a cover sealed to a substrate to form a cavity in accordance with an embodiment of the present invention;

FIG. 3 illustrates curing the adhesive with microwave radiation in accordance with an embodiment of the present invention;

FIGS. 4A-4C illustrate irradiating two thin films of metal to form a single, sealed film of metal in accordance with an embodiment of the present invention;

FIGS. 5A-5D illustrate curing a die attach material with microwave radiation in accordance with an embodiment of the present invention; and

FIGS. 6A-6B and 7A-7B illustrate curing encapsulants with microwave radiation in accordance with embodiments of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a MEMs device sealed within a cavity of a substrate by a cover with an adhesive that has been cured. The invention may also be applied, however, to adhesives and encapsulants in other situations where curing is desired.

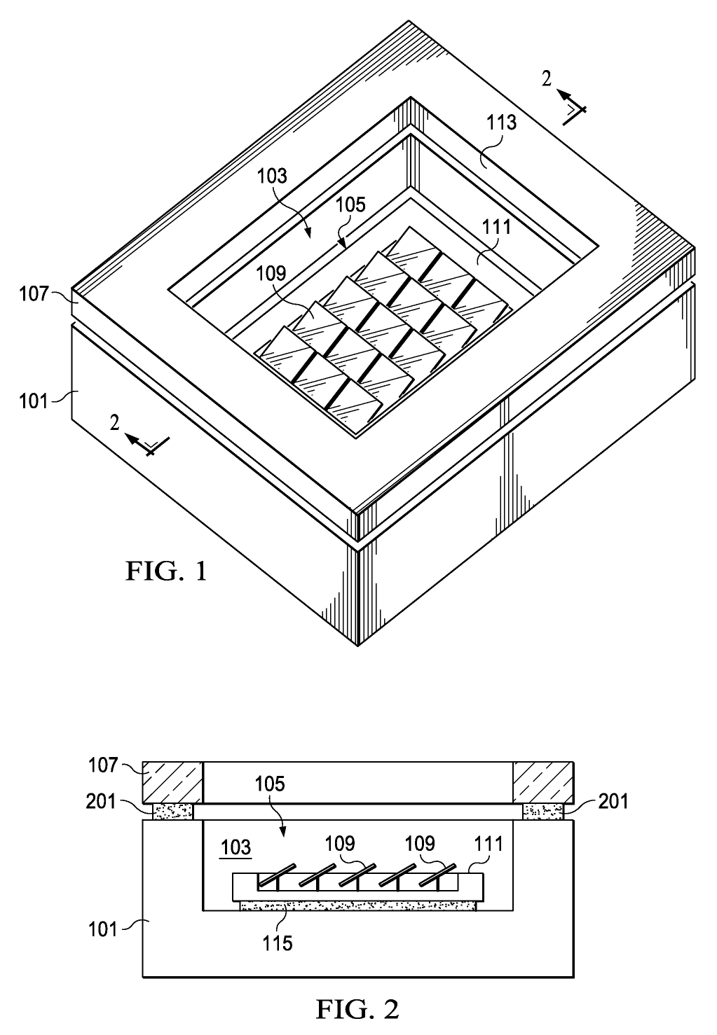

With reference now to FIG. 1, there is shown a substrate 101 with a MEMs device 105 located within a cavity 103 of the substrate 101 and enclosed by a cover 107. In a preferred embodiment, the MEMs device 105 is a digital micromirror device (DMD) with an array of micromirrors 109 formed either on or within a MEMs substrate 111. However, other devices, such as photonic devices, optical devices (e.g., including reflective, refractive and diffractive type devices), or microoptoelectromechanical system (e.g. MOEMS) devices or the like could alternatively be used.

The substrate 101 preferably comprises bulk silicon or an active layer of a silicon-on-insulator (SOI) substrate. Other substrates 101 that may be used include multi-layered substrates, gradient substrate, or hybrid orientation substrates. The substrate 101 is preferably formed so that a cavity 103 is surrounded and partially enclosed by the outer edge of the substrate 101.

The micromirrors 109 are preferably formed on the MEMs substrate 111, which, similar to the substrate 101, may comprise bulk silicon or an active layer of a silicon-on-insulator (SOI) substrate. Other MEMs substrates 111 that may be used include multi-layered substrates, gradient substrate, or hybrid orientation substrates. While only a small number of micromirrors 109 are shown in FIG. 1 for clarity, it should be understood that the actual number of micromirrors 109 is dependent upon the design, and could well exceed over a million distinct micromirrors 109. For example, the array could comprise enough micromirrors 109 to meet resolutions such as 640×480, 720×480, 1280×720, 1920×1080, or other suitable resolutions.

Electrical control circuitry (not shown) is preferably fabricated on or within the surface of the MEMS substrate 111 or the substrate 101 using any suitable integrated circuit process flow. This circuitry preferably includes a memory cell (not shown) associated with, and typically underlying, each micromirror 109 of the array of micromirrors 109 and digital logic circuits to control the transfer of data to the underlying memory cells. Voltage driver circuits to drive bias and reset signals to the micromirrors 109 are preferably fabricated on the MEMs substrate 111, substrate 101, or may alternatively be external to the micromirrors 109.

The micromirrors 109 are preferably formed so as to be rotatable around a torsional hinge connected to the MEMs substrate 111. In operation the electrical control circuitry applies a bias to generate an electrical field in the vicinity of a micromirror 109, which causes the micromirror 109 to rotate to a desired angle. Light impacting the array of micromirrors 109 is preferably modulated by reflecting from a number of micromirrors 109 rotated to one angle, while undesired light is reflected along a separate angle by micromirrors 109 rotated to a second angle.

The cover 107 is preferably located relative to the substrate 101 so as to enclose the MEMs device 105 within the cavity 103. The cover 107 may be completely opaque or completely transparent, depending upon the particular MEMs device 105 that is being enclosed. However, for a DMD device the cover 107 is preferably opaque while additionally having a transparent window 113 to allow for the passage of light into and out of the cavity 103. This usage of a window 113 assures that light from outside the cavity 103 is limited to a more specific or precise area on the MEMs substrate 111. The cover 107 preferably has a thickness of between about 0.7 mm and about 3 mm, with a preferred thickness of about 1.1 mm.

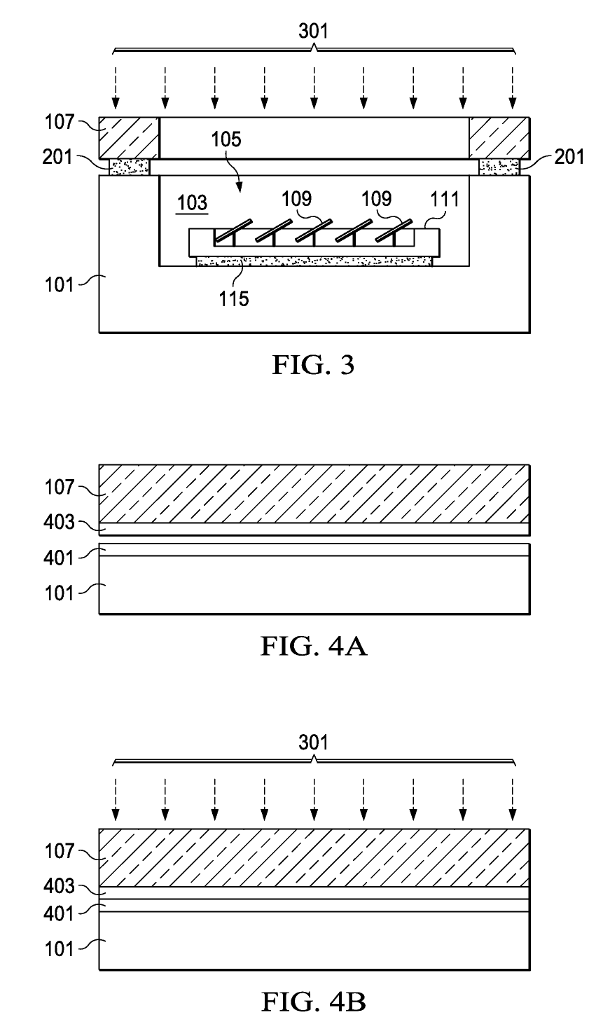

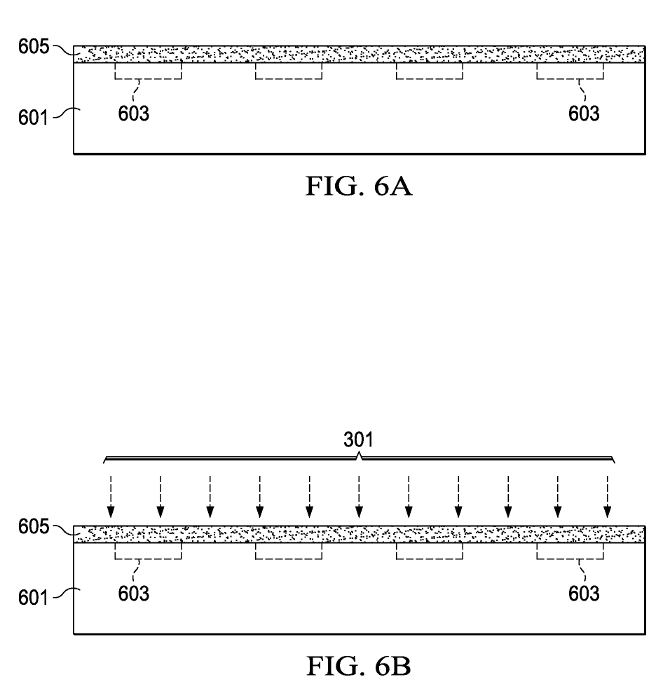

FIG. 2 illustrates a side view of the structure of FIG. 1 along line 2-2′. This view more clearly illustrates the MEMs device 105 located within the cavity 103 formed between the substrate 101 and the cover 107. Additionally, FIG. 2 illustrates an adhesive 201 located between the cover 107 and substrate 101 and a die attach material 115 (more fully described below with respect to FIG. 5A) between the substrate 101 and the MEMs substrate 111. The adhesive 201 is used to hold the cover 107 in place over the substrate 101, and may additionally be used to hermetically seal the cavity 103 so as to isolate the MEMs device 105 from the surrounding ambient environment.

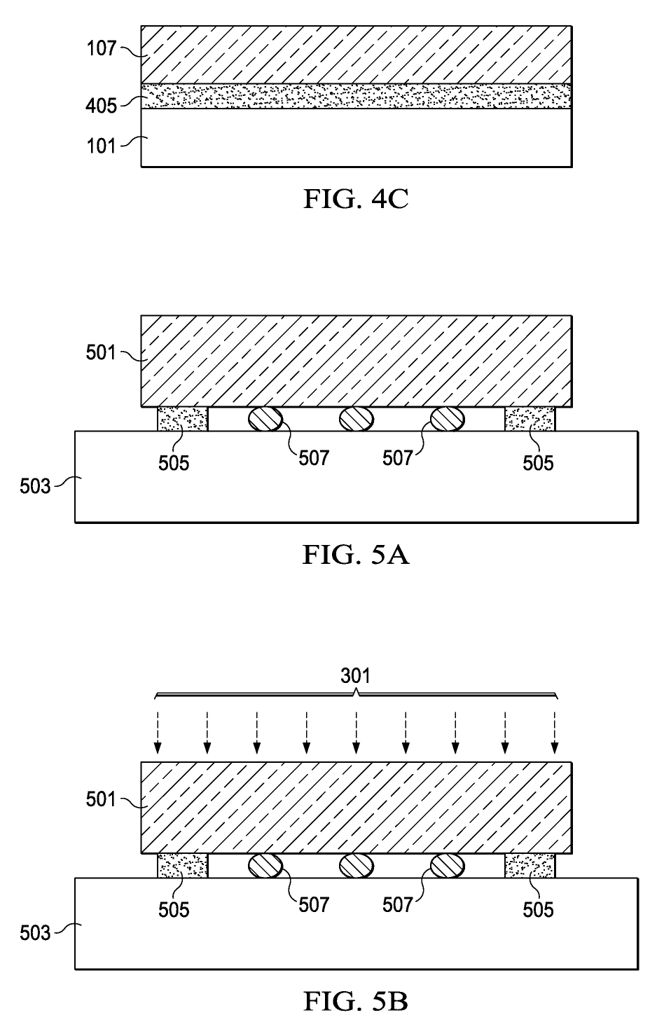

The adhesive 201 preferably comprises an epoxy material that contains polar polymers, such as Henkel's Hysol® QMI505MT™ adhesive. However, any adhesive 201 that may be brought to a curable temperature by microwave radiation (as more fully discussed below with respect to FIG. 3) may alternatively be used. For example, polymers, silicone, related co-polymers, metals (such as Au, Ag, Cu, Al, or Sn), combinations of these, or the like may alternatively be used instead of an epoxy. The adhesive 201 is preferably initially formed with a thickness of between about 10 μm to about 100 μm, with a preferred thickness of about 50 μm.

FIG. 3 illustrates that after the adhesive 201 has been applied and the cover 107 has been aligned with the substrate, the adhesive 201 is cured by irradiating the adhesive 201 with microwave radiation 301 (represented by arrows in FIG. 3). The microwave radiation 301 is used to generate heat in the adhesive 201 at the molecular level by forcing any polar bonds in the adhesive 201 to oscillate. Further, the use of microwave radiation 301 also allows the microwave radiation 301 to be chosen so as to heat the adhesive 201 without significantly heating the other structures, such as the cover 107 or the substrate 101.

This heating preferably heats the adhesive 201 volumetrically at all points within the adhesive. This type of heating does not depend upon a heating of only the outer skin of the adhesive 201 followed by thermal conductivity to the interior of the adhesive 201. However, if a metal is used as the adhesive 201, then the adhesive 201 will alternatively be heated by the microwave radiation 301 at the outer skin, followed by a heat transfer to the interior of the adhesive 201.

Using the microwave radiation 301 to heat the adhesive 201 with polar bonds additionally allows the curing process to self regulate itself. As stated, forced oscillations of the polar bonds cause the adhesive 201 to be heated by the microwave radiation 301. However, once the individual molecules of the adhesive 201 have been heated to the cure temperature, the molecules will react, thereby significantly reducing or eliminating the polar bonds. After the reaction has occurred, there are less polar bonds that are heated by the microwave radiation 301, thereby resulting in less heat generated after the reaction, and stopping the curing process once the adhesive 201 has cured.

The frequency of the microwave radiation 301 necessary to cure the adhesive 201 is dependent upon the precise material to be used as the adhesive 201, but a preferred frequency of about 6.4 GHz is typical. Further, for the preferred materials, the frequency of the microwave radiation 301 is preferably within the microwave band between about 1.0 GHz and about 1,000 GHz. More preferably, the frequency of the microwave radiation 301 is within the C band of microwave radiation, between about 5.8 GHz and about 7.0 GHz.

It is further preferred that the frequency of the microwave radiation 301, once chosen based upon the material to be used as the adhesive 201, be generated as a variable frequency microwave radiation. In other words, once a primary frequency has been chosen for the curing process (based upon the specific adhesive chosen), it is preferred that the curing of the material occur such that the actual frequency sweeps through a range of frequencies centered around the chosen frequency, with a preferred range of about ±0.6 GHz from the central frequency.

The precise number of distinct frequencies generated are dependent upon the material, but a preferred number is about 4000 distinct frequencies centered around the central frequency, with an even more preferred number of 4096 distinct frequencies. Preferably, a complete sweep through the range of frequencies is completed within about 0.1 seconds to about 60 seconds, with a preferred completion time of about 0.1 seconds. Further, it is preferable to have a minimum time of about 25 μs per each frequency.

The microwave radiation 301 is preferably directed towards the adhesive 201 such that the microwave radiation 301 strikes the plane the adhesive 201 is located in perpendicularly, as illustrated in FIG. 3. Alternatively, the microwave radiation 301 may be directed towards the adhesive 201 such that it strikes at any angle. However, other angles might result in a slower curing time.

The microwave curing process is preferably controlled using a closed loop control. This is preferably implemented with an infrared thermometer that can accurately measure the temperature of the adhesive 201. Traditionally, convection based thermal cures are normally controlled in an open loop system relying upon thermocouples placed within the oven and not necessarily indicative of the temperature of the adhesive 201. By using a closed loop control system, a more precise control can be implemented, resulting in even further reductions in time and expense.

The microwave curing is preferably performed after the placement of the cover 107 and prior to any handling of the substrate 101/cover 107 structure, so as to avoid any movement of the cover 107 after alignment and placement. The microwave curing is preferably performed in situ within the same chamber as the placement of the cover 107, although an in-line machine may also be used at a point later in the process from the placement.

The curing of the adhesive 201 is preferably performed in one of two possible methods. In one method, the adhesive 201 is preferably fully cured by a single irradiation of microwave radiation 301. In a full cure the adhesive 201 is irradiated with the microwave radiation 301 for a sufficient time to fully harden and seal the cover 107 to the substrate 101. This time is dependent upon the material chosen, but is preferably greater than about 60 seconds. This time is a large reduction from the usual 3-4 hour cure that would normally be required for a full thermal cure as in the prior art.

In an alternative method, the adhesive 201 is preferably only partially cured using the microwave radiation 301. In a partial cure the adhesive 201 is irradiated with the microwave radiation 301 for only a fraction of the time necessary for a full cure. By partially curing and hardening the adhesive 201, the cover 107 becomes at least partially set and much more resistant to any mis-alignments that may be caused by subsequent handling of the substrate 101/cover 107 structure. Further, because a partial cure is preferably performed for a time period less than about 60 seconds, and more preferably for between about 1 second to about 10 seconds, the partial cure may be performed with virtually no loss of cycle time, allowing for more flexibility in the manufacturing process prior to a full cure of the adhesive 201.

Subsequent to a partial cure of the adhesive 201, the adhesive 201 will still preferably need to be completely cured by another curing process. This subsequent curing process may be either another microwave radiation curing process, a thermal curing process, or any other suitable curing process to complete the partial cure of the adhesive 201. Alternatively, the adhesive 201 may be fully cured using a multi-step curing process incorporating a number of separate suitable curing processes.

However, significant time and energy savings may still be had by using the partial cure method, as the subsequent cures will not need as long a time or as much energy, which will also result in less stress on the wafer, thereby resulting in fewer defects and higher yields. For example, a partial cure with microwave radiation 301 followed by a thermal cure would only require about an hour for the thermal cure, a potential 75% savings in time over using a thermal cure as the only cure.

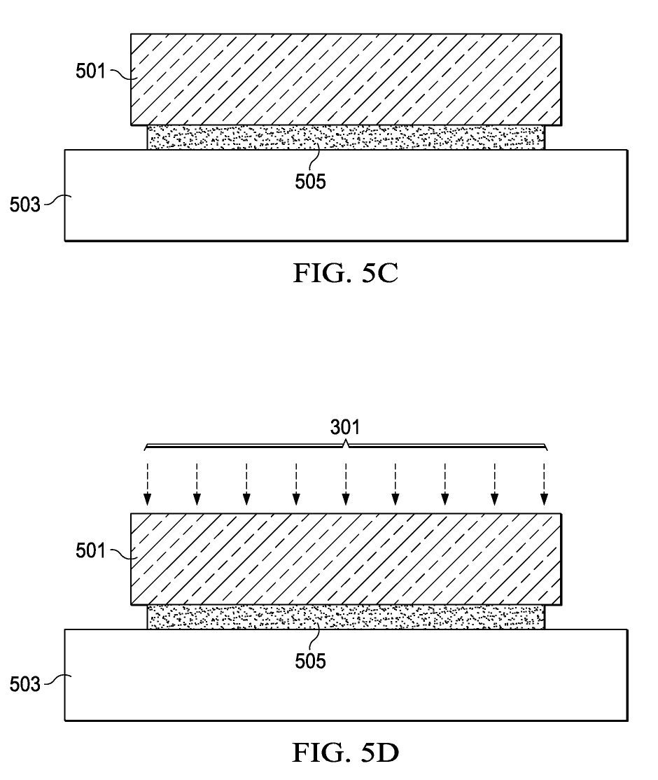

FIG. 4A illustrates an enlarged view of the contact area between the cover 107 and the substrate 101 in another adhesion process that uses two metal layers to adhere the cover 107 to the substrate 101. In this process a first thin film of metal 401 is formed on the substrate 101 by any suitable means. Additionally, a second thin film of metal 403 is formed on the cover 107. The first thin film of metal 401 and the second thin film of metal 403 preferably comprise Au, although other metals, such as Ag, Cu, Al, Sn, combinations of these, or the like may alternatively be used. Further, the first thin film of metal 401 and second thin film of metal 403 are preferably formed to have a thickness of between about 0.0001 μm to about 500 μm for each layer, with a preferred thickness of about 2 μm.

FIG. 4B illustrates that, once the cover 107 has been positioned over the substrate 101 such that the first thin film of metal 401 and the second thin film of metal 403 are in contact, the two thin films of metal are preferably irradiated by microwave radiation 301, as discussed above with respect to FIG. 3, in order to raise the temperature of the first thin film of metal 401 and the second thin film of metal 403 to their melting points. However, because metals are being used instead of polar polymers, only the exterior of the first thin film of metal 401 and the second thin film of metal 403 will be heated by the microwave radiation 301.

FIG. 4C illustrates the final structure of this process after the microwave radiation 301 has heated the exterior of the first thin film of metal 401 and the second thin film of metal 403 to their melting points. This partial heating is sufficient to reflow the two thin films of metal into a single film of adhesive metal 405 to seal the cover 107 to the substrate 101.

Alternatively, instead of the first thin film of metal 401 and the second thin film of metal 403, a single layer of a material such as solder may be used. This material is preferably heated by the microwave radiation 301 above its melting point in order to reflow the solder. Once cooled, the solder forms a seal between the cover 107 and the substrate 101.

FIG. 5A illustrates another embodiment of the present invention whereby a die attach material 505 may be cured using the microwave radiation 301. In this process a semiconductor die 501 is preferably bonded to a substrate 503, which is preferably either another wafer (as in wafer bonding) or else a printed circuit board, such as in flip-chip bonding. The die attach material 505 may be similar to the adhesive 201 described above with reference to FIG. 2, with a similar thickness as well.

Prior to curing the die attach material 505, the semiconductor die 501 and the substrate 503 are positioned and aligned with each other. Proper alignment between the semiconductor die 501 and the substrate 503 ensures any contacts 507 between the semiconductor die 501 and the substrate 503 are properly aligned.

FIG. 5B illustrates that, once aligned, the die attach material 505 is preferably irradiated by microwave radiation 301 as discussed above with respect to FIG. 3. Notably, as discussed above, the die attach material 505 may at this time be either fully cured or else partially cured by the microwave radiation 301. Further, the microwave radiation 301 is preferably variable microwave radiation, and the cure may be performed either in situ at the point of alignment in the process or else at a later stage in the process.

This process again allows for a selective heating of just the die attach material 505 without significant heating of the surrounding materials. This helps relieve stress normally caused by differing rates of thermal expansion of the different materials, working to reduce defects and increase yield.

FIG. 5C illustrates an alternative die attach process, whereby the semiconductor die 501 is attached to the substrate 503 with a layer of die attach material 505. In this embodiment the die attach material 505 covers a majority of the surfaces between the semiconductor die 501 and the substrate 503. The die attach material 505 may be similar to the adhesive 201 described above with reference to FIG. 2, with a similar thickness as well.

FIG. 5D illustrates that once the semiconductor die 501 and the substrate 503 are aligned and positioned and in contact with the die attach material 505, microwave radiation 301 is utilized to cure the die attach material 505 and attach the semiconductor die 501 to the substrate 503. This curing process is similar to the curing process described above with respect to FIG. 3. Notably, the cure of the die attach material 505 may be performed using variable microwave radiation in situ with the positioning, and the die attach material 505 may be completely cured in a single step or else cured using multiple steps.

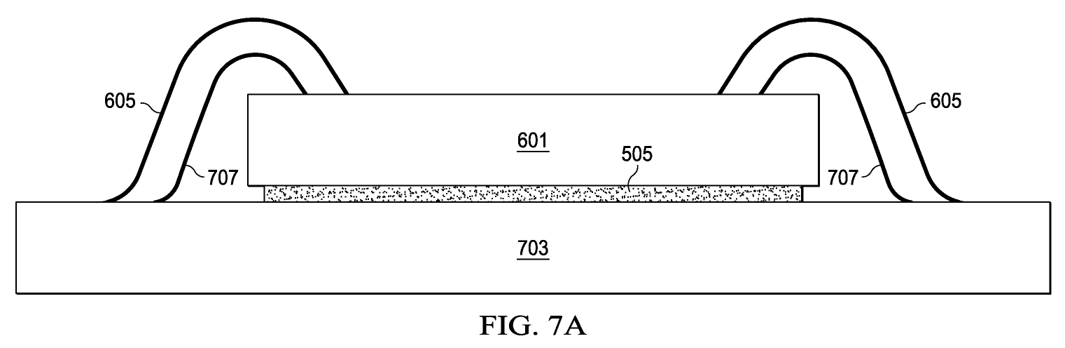

FIG. 6A illustrates yet another embodiment of the present invention in which an encapsulant 605 is cured using the microwave radiation 301. In this embodiment a die 601 has integrated circuitry 603 (represented by the dashed boxes) formed within and on the surface of the die 601. To protect the integrated circuitry 603 and interconnects from environmental hazards, the die 601 is encapsulated with an encapsulant 605 to seal the die 601.

The encapsulant 605 is preferably an epoxy similar to the adhesive described above with respect to FIG. 3. However, other materials, such as a polyamide adhesive, a thermoset resin, a silicone-based elastomeric, or a low viscosity molding compound filled with silica and anhydrides, combinations of these, or the like, may alternatively be used. The encapsulant 605 is preferably formed over the die 601 with a thickness of between about 100 μm and about 10 mm, with a preferred thickness of about 2 mm.

FIG. 6B illustrates that once the encapsulant 605 has been formed over the die 601, the encapsulant 605 is preferably cured using microwave radiation 301 as described above with respect to FIG. 3. Notably, the encapsulant 605 is preferably cured using variable frequency microwaves whose central frequency is dependent upon the particular encapsulant 605 used. Additionally, the encapsulant 605 may be either fully cured or else partially cured by microwave radiation 301.

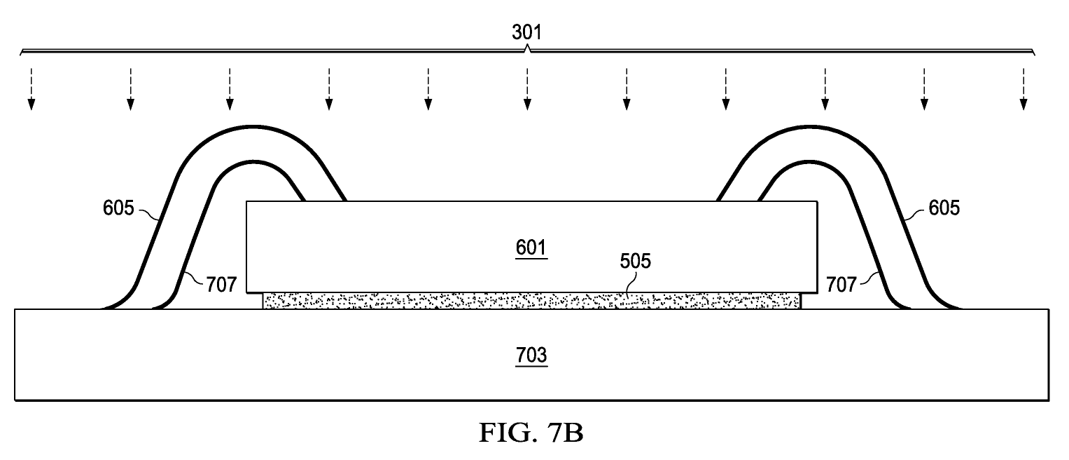

FIG. 7A illustrates yet another embodiment of the present invention in which an encapsulant 605 is cured using the microwave radiation 301. In this embodiment the die 601 is preferably attached to a substrate 703 using the die attach material 505 (described with respect to FIG. 5A). Wire bonds 707 are attached to form connections between the die 601 and the substrate 703. To protect these wire bonds 707, the encapsulant 605 is formed to enclose and protect the wire bonds 707. Preferably, while enclosing and protecting the wire bonds 707, the encapsulant 605 only covers a portion of the die 601, although a complete encapsulation of the die 601 could alternatively be utilized if required.

FIG. 7B illustrates that once the encapsulant 605 has been formed over the wire bonds 707, the encapsulant 605 is preferably cured using microwave radiation 301 as described above with respect to FIG. 3. Notably, the encapsulant 605 is preferably cured using variable frequency microwaves whose central frequency is dependent upon the particular encapsulant 605 used. Additionally, the encapsulant 605 may be either fully cured or else partially cured by microwave radiation 301.

Although the present invention and its advantages have been described in detail, it should be understood that various changes, substitutions and alterations can be made herein without departing from the spirit and scope of the invention as defined by the appended claims. For example, it will be readily understood by those skilled in the art that many different types of adhesives or encapsulants may be used while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for curing a semiconductor device adhesive, the method comprising:
providing a substrate and a cover;
applying an adhesive to at least one of the substrate or the cover;
placing the substrate and the cover in contact with the adhesive; and
volumetrically heating the adhesive with microwave radiation.

2. The method of claim 1, wherein the microwave radiation is a variable frequency microwave radiation.

3. The method of claim 1, wherein the heating the adhesive is ended prior to the adhesive being completely cured.

4. The method of claim 3, wherein the volumetrically heating the adhesive lasts no longer than about 10 seconds.

5. The method of claim 3, further comprising heating the adhesive with a thermal heat.

6. The method of claim 3, further comprising repeating the volumetrically heating the adhesive with microwave radiation.

7. The method of claim 1, wherein the heating the adhesive is continued until the adhesive is completely cured.

8. The method of claim 7, wherein the heating the adhesive is continued for longer than about 60 seconds.

9. The method of claim 1, wherein the heating the adhesive with microwave radiation is performed in situ with the placement of the cover on the substrate.

10. The method of claim 1, wherein the heating the adhesive with microwave radiation is performed at a separate location from the placement of the cover on the substrate.

11. The method of claim 1, wherein the microwave radiation is within the C band of microwave radiation.

12. A method for bonding a semiconductor die to a substrate, the method comprising:
providing the substrate and the semiconductor die;
adhering the semiconductor die to the substrate by applying a single layer of an attach material between the substrate and the semiconductor die;
at least partially curing the attach material by heating the attach material using microwave radiation.

13. The method of claim 12, further comprising thermally curing the attach material.

14. The method of claim 12, further comprising repeating the at least partially curing the attach material by heating the attach material using microwave radiation.

15. The method of claim 12, wherein the at least partially curing the attach material is performed prior to moving the wafer and substrate.

16. The method of claim 12, wherein the microwave radiation is a variable frequency microwave radiation.

17. A method of encapsulating a semiconductor device, the method comprising:
providing a semiconductor device;
applying an encapsulant to the semiconductor device;
irradiating the encapsulant with microwave radiation to at least partially cure the encapsulant.

18. The method of claim 17, further comprising irradiating the encapsulant with microwave radiation until the encapsulant is completely cured.

19. The method of claim 17, further comprising thermally curing the encapsulant subsequent to the irradiating the encapsulant.

20. The method of claim 17, wherein the microwave radiation is a variable frequency microwave radiation.
